(19) United States
(12) Patent Application Publication
(10) Pub. No.: US 2024/0349563 A1
(43) Pub. Date: Oct. 17, 2024

(54) DISPLAY DEVICE HAVING ORGANIC LIGHT EMITTING ELEMENT

(71) Applicant: Samsung Display Co., LTD., Yongin-si (KR)

(72) Inventors: Sangho JEON, Yongin-si (KR); Yo Sub KO, Yongin-si (KR); Jungmin MOON, Yongin-si (KR); Jeong Su PARK, Yongin-si (KR); Dong Hoon KIM, Yongin-si (KR)

(73) Assignee: Samsung Display Co., LTD., Yongin-si (KR)

(21) Appl. No.: 18/526,013

(22) Filed: Dec. 1, 2023

(30) Foreign Application Priority Data
Apr. 10, 2023 (KR) 10-2023-0046970

(51) Int. Cl. H10K 59/35; G09G 3/3241

(52) U.S. Cl. CPC H10K 59/35; G09G 3/3241; H10K 2101/40; H10K 2102/361

(57) ABSTRACT

A display device includes a red pixel, a green pixel, and a blue pixel comprising a plurality of transistors and an organic light emitting element. The organic light emitting element has a value of a temperature sensitive factor (TSF) in a range of about 0.25×10⁻¹ Cd·m²/V to about 0.51×10⁻¹ Cd·m²/V as shown in a following equation:

$$T S F = \frac{d ( \frac{Δ L ( c , T )}{Δ J ( c , T )} )}{dV ( c )} ,$$

where, ΔJ is the amount of change in current density, ΔL is the amount of change in luminance, V is the voltage, a variable c is the color, and T is a temperature.

### CROSS-REFERENCE TO RELATED APPLICATION(S)

This application claims priority to and benefits of Korean Patent Application No. 10-2023-0046970 under 35 U.S.C. § 119, filed at the Korean Intellectual Property Office on Apr. 10, 2023, the entire contents of which are incorporated herein by reference.

### BACKGROUND

### 1. Field of the Invention

The disclosure relates to a display device comprising an organic light emitting element.

### 2. Description of Related Art

A display device is a device for displaying an image, and organic light emitting devices (organic light emitting diode displays) have recently attracted attention.

An organic light emitting display device has a self-emitting characteristic including an organic light emitting element, and unlike a liquid crystal display device, it does not require a separate light source, thereby reducing thickness and weight.

In addition, an organic light emitting display device exhibits high-grade characteristics such as low power consumption, high brightness, and high response speed.

In general, an organic light emitting display device may include a substrate, multiple thin film transistors positioned on a substrate, multiple insulating layers disposed between wires constituting a thin film transistor, and an organic light emitting element receiving current from a thin film transistor.

At least two thin film transistors may be used to allow one organic light emitting element to emit light.

### SUMMARY

Embodiments are intended to provide a display device including an organic light emitting element whose luminance does not change depending on temperature. This is to determine whether luminance is changed according to temperature through a test of an organic light emitting element.

An embodiment may include a red pixel, a green pixel, and a blue pixel that each include a plurality of transistors and an organic light emitting element. The organic light emitting element may have a value of a temperature sensitivity factor (TSF) in a range of about 0.25×10⁻¹ Cd·m²/V to about 0.51×10⁻¹ Cd·m²/V as shown in a following equation:

$$T S F = \frac{d ( \frac{Δ L ( c , t )}{Δ J ( c , T )} )}{dV ( c )} ,$$

where ΔJ is an amount of change in current density, where ΔL is an amount of change in luminance, where V is a voltage, where a variable c is a color, and where T is a temperature.

The temperature sensitivity factor (TSF) may be a tangential slope on a graph with an x-axis as a voltage and a y-axis as ΔL/ΔJ.

A driving voltage for the organic light emitting element of the blue pixel may have a higher voltage than a driving voltage for the organic light emitting element of the red pixel and a driving voltage for the organic light emitting element of the green pixel.

The driving voltage for the organic light emitting element of the blue pixel may have a voltage in a range of about 2.04V to about 2.64V, and the driving voltage for the organic light emitting element of the red pixel and the driving voltage for the organic light emitting element of the green pixel may each be in a range of about 1.6V to about 2.2V.

Even in case that the temperature of the organic light emitting element of at least one of the red pixel, the green pixel, and the blue pixel is changed, the luminance may be changed to within about 5% with respect to a reference luminance.

An expected value (TEGAL) of a luminance change of the organic light emitting element of at least one of the red pixel, the green pixel, and the blue pixel may satisfy a following equation:

$$TEG Δ L ( c , T , G ) = ( 1 + \frac{d ( \frac{Δ L ( c , t )}{Δ j ( c , T )}}{dV ( c )} \times \frac{1}{α} \frac{J ( c , {G}_{0} )}{J ( c , G )} \times Op . V ( c , G ) \times ( Δ J ( c , T , G ) \times LL ) ) \times 100 ,$$

where Op.V may be a driving voltage, LL may be a lateral leakage factor, and a may be a constant.

The amount of change of a current density value (ΔJ(c, T, G)) included in an expected value of a luminance change satisfies the following equation, and may have a value in a range of about 289% to about 329%:

$$Δ J ( c , T , G ) = \frac{J ( c , T , G )}{J ( C , {T}_{0} , G )}$$

The lateral leakage factor LL may satisfy a following equation:

$$LL = 1 - ( \frac{β \times Δ Cap ( c , T ) \times \vert Δ Op . V ( c , T , G ) \vert}{Op . V ( c , G )} ) ,$$

where Cap may be a capacitance and α may be a constant.

An amount of change in capacitance (ΔCap(c, T)) among lateral leakage factors may satisfy a following equation:

$$Δ Cap ( c , T ) = \vert \frac{{Cap}_{m ax}^{′} ( c , T ) - {Cap}_{m ax} ( c , {T}_{0} )}{{Cap}_{m ax}^{′} ( c = Blue , T ) - {Cap}_{m ax} ( c = Blue , {T}_{0} )} \vert \times \frac{{Cap}_{m ax}^{′} ( c , T )}{{Cap}_{m ax} ( c , T )} ,$$

where Cap′max satisfies a following equation

$${Cap}_{m ax}^{′} ( c , T ) = {Cap}_{ma x} ( c , T ) / {ΔV}_{ma x} ( c , T )$$

where an amount of change of a maximum voltage ΔVₘₐₓ may satisfy a following equation:

$${ΔV}_{ma x} ( c , T ) = {V}_{ma x} ( c , T ) / {V}_{ma x} ( c , {T}_{0} ) .$$

The amount of change in capacitance may have a value of about 1000% or more, and the amount of change in capacitance of the red pixel or the organic light emitting element of the green pixel with respect to the organic light emitting element of the blue pixel may have a value of about 10 times or more.

The organic light emitting element of at least one of the red pixel, the green pixel, and the blue pixel may have a mobility of about 1e⁻⁶ cm²/V·s or more.

The organic light emitting element of at least one of the red pixel, the green pixel, and the blue pixel may include an anode, a first functional layer, an emission layer, a second functional layer, and a cathode, and the energy gap between two adjacent layers among the anode, the first functional layer, the emission layer, the second functional layer, and the cathode may be less than about 0.2 eV each.

An embodiment may include a display device that may include a red pixel, a green pixel, and a blue pixel that each include a plurality of transistors and an organic light emitting element. The organic light emitting element may have a value of about 1000% or more of an amount of change in a capacitance (ΔCap(c, T)) as shown in a following equation:

$$Δ Cap ( c , T ) = \vert \frac{{Cap}_{m ax}^{′} ( c , T ) - {Cap}_{m ax} ( c , {T}_{0} )}{{Cap}_{m ax}^{′} ( c = Blue , T ) - {Cap}_{m ax} ( c = Blue , {T}_{0} )} \vert \times \frac{{Cap}_{m ax}^{′} ( c , T )}{{Cap}_{m ax} ( c , T )} ,$$

where a variable c may be color, where T may be temperature, where To may be about 25° C., where Cap may be a capacitance, where Cap′max satisfies a following equation:

$${Cap}_{m ax}^{′} ( c , T ) = {Cap}_{ma x} ( c , T ) / {ΔV}_{ma x} ( c , T ) ,$$

where a maximum voltage change (ΔVmax) satisfies the following equation:

$${ΔV}_{ma x} ( c , T ) = {V}_{ma x} ( c , T ) / {V}_{ma x} ( c , {T}_{0} ) .$$

An amount of change in capacitance of the organic light emitting element of the red pixel or the organic light emitting element of the green pixel may have a value of about 10 times or more with respect to the organic light emitting element of the blue pixel.

A lateral leakage factor LL may satisfy a following equation:

$$Δ Cap ( c , T ) = Δ Cap ( T ) \times Δ Cap ( c ) ,$$

where Δcap(T) may be an amount of change in capacitance for each temperature, and Δcap(c) may be an amount of change in capacitance for each color.

A capacitance change according to temperature may have a value in a range of about 392% to about 792%.

A capacitance change according to color may have a value in a range of about 138% to about 278%.

A difference between a driving voltage of the organic light emitting element of the blue pixel and a driving voltage of the organic light emitting element of the red pixel or the organic light emitting element of the green pixel may have a value in a range of about 0.34V to about 0.54V.

The organic light emitting element of at least one of the red pixel, the green pixel, and the blue pixel may have a mobility of about 1e⁻⁶ cm²/V·s or more.

The organic light emitting element may include an anode, a first functional layer, an emission layer, a second functional layer, and a cathode, wherein an energy gap between two adjacent layers among the anode, the first functional layer, the emission layer, the second functional layer, and the cathode may be about 0.2 eV or less.

According to embodiments, based on a test of an organic light emitting element, it may be possible to check whether a corresponding organic light emitting element changes a brightness sensitively with temperature, so that the brightness does not change sensitively with temperature changes and a display device including an organic light emitting element can be formed.

According to embodiments, a temperature sensitivity of an organic light emitting element can be clearly confirmed based on a measured value measured through a TEG (Test Elements Group) to provide a display device with low temperature sensitivity.

### BRIEF DESCRIPTION OF THE DRAWINGS

FIG. 1 is a schematic top plan view of a display device according to an embodiment.

FIG. 2 is a schematic diagram of an equivalent circuit of one pixel included in a display device according to an embodiment.

FIG. 3 is a schematic cross-section view of a test element of a display device according to an embodiment.

FIG. 4 is a table showing the meaning of abbreviations used in the disclosure.

FIG. 5 is a table showing a range that can satisfy the temperature sensitivity of an organic light emitting element according to an embodiment.

FIG. 6 to FIG. 8 are schematic views illustrating the meaning of a formula corresponding to the temperature sensitivity of an organic light emitting element according to an embodiment.

FIG. 9 to FIG. 12 are schematic views showing numerical values corresponding to the temperature sensitivity of an organic light emitting element and a characteristic according to an embodiment, and FIG. 13 is a table of the same.

FIG. 14 is a table showing the range of capacitance values that can satisfy a lateral leakage of an organic light emitting element according to an embodiment.

FIG. 15 and FIG. 16 are schematic views illustrating the meaning of equations corresponding to a lateral leakage of an organic light emitting element according to an embodiment.

FIG. 17 to FIG. 20 are schematic views showing numerical values corresponding to lateral leakage of an organic light emitting element according to an embodiment and characteristics thereof, and FIG. 21 is a table of the same.

FIG. 22 to FIG. 25 are schematic graphs showing the relationship between the expected value of a luminance change with temperature and an actual value.

FIG. 26 to FIG. 28 are schematic graphs describing temperature sensitivity, driving voltage, and capacitance values corresponding to lateral leakage, respectively, according to an embodiment.

FIG. 29 is a table describing conditions according to physical properties of an organic light emitting element according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In order to clearly describe the embodiments, elements irrelevant to the description may be omitted, and the same reference numerals are assigned to the same or similar components throughout the specification.

In addition, since the size and thickness of each component shown in the drawings may be arbitrarily shown for convenience of explanation, the disclosure is not necessarily limited to those shown.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that when an element such as a layer, film, region, or substrate is referred to as being “on” or “over” another element, it can be directly on the other element or intervening element(s) may also be present. In contrast, when an element is referred to as being “directly on” another element, no intervening elements are present.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof. ““””

In addition, in the specification, when “plan” is stated, this means when a target part is viewed from above, and when “cross-section” is stated it mean when a cross-section cut vertically of a target part is viewed from a side.

It will be understood that when an element (or a region, a layer, a portion, or the like) is referred to as being “on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical and/or electrical connection or coupling. ““””

In addition, in the specification, when a portion of a wiring, layer, membrane, region, plate, component, etc. is “extended in a first or second direction,” it does not mean only a straight line shape straight in that direction, but also a structure that extends generally along a first or second direction, and is bent in one part, has a zigzag structure, or extends while including a curved line structure.

In addition, electronic devices (e.g., mobile phones, TVs, monitors, notebook computers) including display devices, display panels, etc., described in the specification, or display devices, display panels, etc., manufactured by a manufacturing method described in the specification, are not excluded from the scope of rights herein.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

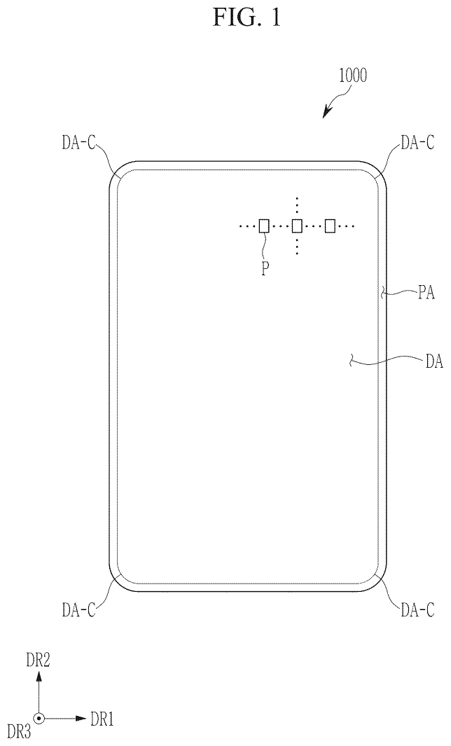

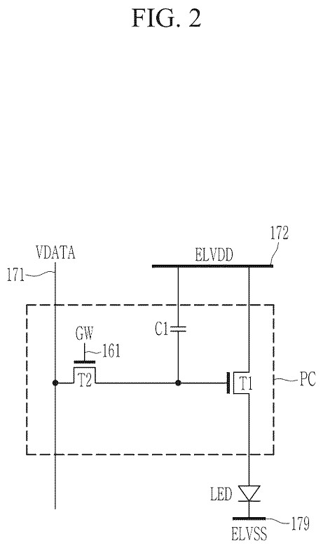

FIG. 1 is a schematic top plan view of a display device according to an embodiment.

Referring to FIG. 1, a display device 1000 according to an embodiment includes a display area DA in which multiple pixels P are disposed and an image is displayed, and a non-display area PA adjacent to a display area DA.

A non-display area PA is a region in which an image may not be displayed.

A display area DA may be a square shape as an example, and according to an embodiment, as shown in FIG. 1, each edge (DA-C) of a display area DA may have a round shape.

A non-display area PA may have a shape that surrounds a display region DA.

However, without limitation, the shape of a display area DA and a non-display area PA may be variously designed.

A display area DA may display an image using multiple pixels P.

A pixel P may include multiple transistors, capacitors, and organic light emitting elements.

A non-display area PA may be made in the form of surrounding a display area DA.

A non-display area PA is a region in which an image may not be displayed, and may be positioned on the outer region of a display device 1000.

At least a portion of a display device 1000 according to an embodiment may be a flexible display device including a bending portion.

For example, the center of a display device 1000 may be flat, and an edge may have a curved shape.

At least a portion of a display area DA may be positioned in a bending portion, so that at least a portion of the display area DA may have a curved shape.

A test element formed by the same process as an organic light emitting element of a pixel P may be formed in a non-display area PA.

A surface on which an image is displayed in a display device 1000 is parallel to a surface defined by a first direction DR1 and a second direction DR2.

A normal direction of one surface on which an image is displayed—that is, a thickness direction of a display device 1000—may be indicated by a third direction DR3.

A front (or top) and back (or bottom) of each member may be distinguished by a third direction DR3.

However, a direction indicated by the first to third directions (DR1, DR2, DR3) can be converted to different directions as they may be relative concepts.

A display device 1000 may further include a touch unit and/or a cover window on an upper side.

A display device 1000 may be a flat rigid display device or, without limitation, a flexible display device.

A display device according to an embodiment may additionally include a color conversion layer including a quantum dot and/or a color filter.

Hereinafter, a basic circuit structure of a pixel P positioned in a display area DA is described through FIG. 2.

FIG. 2 is a schematic diagram of an equivalent circuit of one pixel included in a display device according to an embodiment.

A pixel shown in FIG. 2 may include two transistors T1 and T2, one capacitor C1, and an organic light emitting element LED.

Looking at the structure of FIG. 2, one pixel may include an organic light-emitting element LED and a pixel driving unit PC driving the same.

A pixel driving unit may include all other devices except an organic light emitting element LED in FIG. 2, and a pixel driving unit of a pixel according to an embodiment of FIG. 2 may include a first transistor T1, a second transistor T2, and a first capacitor C1.

A pixel driving unit may be connected to a first scan line 161 to which a first scan signal GW is applied, and a data line 171 to which a data voltage VDATA is applied.

A pixel may be connected to a first driving voltage line 172 to which a driving voltage (ELVDD; a first driving voltage) is applied, and a second driving voltage line 179 to which a driving undervoltage (ELVSS; a second driving voltage) is applied.

Focusing on each element (transistor, capacitor, and organic light emitting element) included in a pixel, the circuit structure of a pixel is as follows.

A first transistor (T1; drive transistor) may include a gate electrode connected to a first electrode of a first capacitor C1 and a second electrode of a second transistor T2, a first electrode (input side electrode) connected to a first driving voltage line 172, and a second electrode (output side electrode) connected to an anode of an organic light emitting element LED.

A first transistor T1 may determine the degree to which a first transistor T1 is turned on according to the voltage of a gate electrode, and the size of a current flowing from a first electrode to a second electrode of the first transistor T1 may be determined according to the degree of turning on.

A current flowing from a first electrode to a second electrode of a first transistor T1 may be transmitted to an anode of an organic light emitting element LED, and may also be referred to as a light emitting current.

Here, a first transistor T1 may be formed as an n-type transistor, and a higher voltage of a gate electrode, and thus a greater light emitting current, can flow.

In case that an emitting current is large, an organic light emitting element LED can display high brightness.

A second transistor (T2: data input transistor) may include a gate electrode connected to a first scan line 161 to which a first scan signal GW is applied, a first electrode (input side electrode) connected to a data line 171 to which a data voltage VDATA is applied, and a first electrode of a first capacitor C1 and a second electrode (output side electrode) connected to a gate electrode of a first transistor T1.

A second transistor T2 may input a data voltage VDATA into a pixel according to a first scan signal GW and transmit it to a gate electrode of a first transistor T1, and can be stored in a first electrode of a first capacitor C1.

All transistors may be formed of n-type transistors, and each transistor can be turned on in case that the voltage of a gate electrode is a high-level voltage and a low-level voltage can be turned off.

A semiconductor layer included in each transistor may use a polycrystalline silicon semiconductor or an oxide semiconductor, and may additionally use an amorphous semiconductor or a monocrystalline semiconductor.

According to an embodiment, the semiconductor layer included in each transistor may further include an overlapping layer (or additional gate electrode) overlapping thereto, and a voltage may be applied to the superposition layer (additional gate electrode) to change the characteristics of the transistor to further improve the display quality of the pixel.

A first capacitor C1 may include a first electrode connected to a gate electrode of a first transistor T1, a second electrode of a second transistor T2 and a second electrode for receiving a first driving voltage ELVDD.

A first electrode of a first capacitor C1 may receive and store a data voltage VDATA from a second transistor T2.

An organic light emitting element LED may include a cathode connected to a second driving voltage line 179 to receive a second driving voltage ELVSS and an anode connected to a second electrode of a first transistor T1.

An organic light-emitting element LED may be positioned between a pixel driving unit and a second driving voltage ELVSS and an equal electric current may flow to a current flowing through a first transistor T1 of a pixel driving unit, and a luminance to be emitted may also be determined according to the size of the current.

An organic light emitting element LED may include an emission layer in which an organic light emitting material is positioned between an anode and a cathode.

A hole injection layer and/or hole transfer layer may be further positioned between an anode and an emission layer, and an electron transfer layer and/or electron injection layer may be further positioned between a cathode and an emission layer.

In the embodiment of FIG. 2, it is depicted that one pixel P includes two transistors T1, T2 and one capacitor (the first capacitor C1), but the disclosure is not limited thereto.

According to an embodiment, a transistor may be formed into a p-type transistor.

A pixel according to an embodiment may include two transistors, one capacitor, and an organic light emitting element, but may have a connection relationship different from FIG. 2.

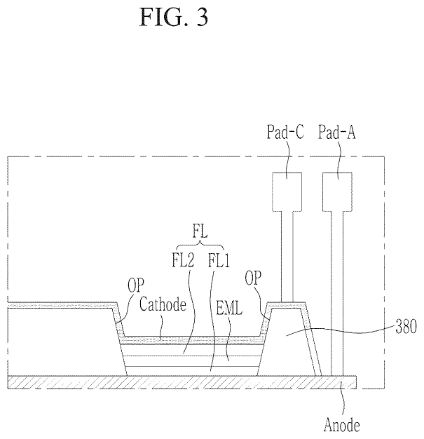

Hereinafter, a schematic cross-sectional structure of the test element formed in the non-display area PA for testing, although formed in the same process as the organic light emitting element LED of the pixel positioned in the display area DA, will be discussed with respect to FIG. 3.

FIG. 3 is a schematic cross-section view of the test element of the display device according to an embodiment.

The test element shown in FIG. 3 is produced with the same material and the same process as the stacking structure of the organic light emitting element of the pixel positioned in the display area DA, and may have the same stacked structure.

Based on FIG. 3, the schematics of the stacking structure of the test element are as follows.

An anode may be positioned on the organic layer (not shown).

Here, the anode may be composed of a single layer including a transparent conductive oxide film or a metal material, or a multiple layer including the same.

The transparent conductive oxide layer may include indium tin oxide ITO, poly-ITO, indium zinc oxide IZO, indium gallium zinc oxide IGZO, and/or indium tin zinc oxide ITZO.

The metal material may include silver (Ag), molybdenum (Mo), copper (Cu), gold (Au), and/or aluminum (Al).

A pixel defining layer 380 including an opening OP may be formed on the anode.

An opening (OP; hereinafter, also referred to as a light emitting device opening) of the pixel defining layer 380 may be a region corresponding to a planar organic light emitting element, and an emission layer EML may be formed therein.

The first functional layer FL1 may be positioned between the anode and the emission layer EML, and the second functional layer FL2 may be positioned above the emission layer EML and between the cathode.

Here, the first functional layer FL1 may include a hole injection layer and/or a hole transport layer, and the second functional layer FL2 may include an electron transport layer and/or an electron injection layer.

Here, the functional layer FL and the emission layer EML may be referred to as an intermediate layer.

Depending on the embodiment, the first functional layer FL1 and the second functional layer FL2 may also be formed on the pixel defining layer 380.

A cathode may be formed on the second functional layer FL2 and on the pixel defining layer 380 and the opening OP.

Here, the cathode may be formed of a transparent conductive layer including indium tin oxide ITO, indium zinc oxide IZO, indium gallium zinc oxide IGZO, and indium tin zinc oxide ITZO.

Also, the cathode may have a translucent property.

As described above, multiple test elements may be formed in the non-display area PA, and a cross-sectional structure of the test elements may be the same as a stacked structure of the organic light emitting element formed in the display area DA.

The organic light emitting element formed in the display area DA may include an anode, an emission layer EML, and a cathode, and additionally, a first functional layer FL1 and a second functional layer FL2 may be further provided.

In the display area DA, a transistor and a capacitor may be formed below the organic layer, and the transistor and the anode may be electrically connected to each other in the display area DA.

As a result, in the display area DA, the anode may receive current from the transistor positioned below the organic layer, and the current transferred to the anode may be transmitted through the first functional layer FL1, the emission layer EML, and the anode. It may pass through the second functional layer FL2 and may be transferred to the cathode.

At this time, the emission layer EML may emit light due to the current flowing through the emission layer EML, and the organic light emitting element may exhibit luminance.

The test element formed in the non-display area PA shown in FIG. 3 may have the same characteristics as the organic light emitting element formed in the display area DA because it may be formed of the same material and by the same process.

As a result, a test result by applying current or voltage to the test element formed in the non-display area PA may correspond to the characteristics of the organic light emitting element formed in the display area DA.

Therefore, hereinafter, the test element formed in the non-display area PA may be tested to determine whether the organic light emitting element formed in the display area DA causes a small change in luminance, gamma, and color with temperature.

For example, in case that the display luminance, gamma, and color change according to the temperature at which the display device is used, there may be a problem that the display quality is not consistent.

Therefore, hereinafter, using the result value measured from the test element, in case that certain conditions are satisfied and the sensitivity according to temperature is low, the display quality can be formed.

On the other hand, according to an embodiment, in order to grasp the characteristics of the emission layer, the organic light emitting element may be stacked separately from the display device and formed, and the test may be performed.

Referring to FIG. 3, it is shown that a pad A (Pad-A) may be connected to the anode of the test element and a pad C (Pad-C) may be connected to the cathode.

For example, in order to test the test element formed in the non-display area PA, voltage and current may be provided to each pad (Pad-A, Pad-C), and the values of current, voltage, capacitance, etc. may be measured. By measuring the luminance of light emitted from the emission layer EML and using this to determine whether it is within a certain range, it may be possible to determine whether the sensitivity according to temperature is low.

Here, values measurable through the test device may be classified into two groups, and each group may be measured through a separate test.

The first measurement group may correspond to a J-V-L characteristic test, including luminance, current (or current density), and voltage, and the second measurement group may correspond to a C-V characteristic test, including capacitance and voltage.

According to an embodiment, an expected value of luminance change (TEGAL (c, T, G)) as shown in equation 1 can be obtained using each value calculated through the test device.

$$TEG Δ L ( c , T , G ) = ( 1 + \frac{d ( \frac{Δ L ( c , T )}{Δ J ( c , T )}}{dV ( c )} \times \frac{1}{α} \frac{J ( c , {G}_{0} )}{J ( c , G )} \times Op . V ( c , G ) \times ( Δ J ( c , T , G ) \times LL ) ) \times 100 \qquad [ equation 1 ]$$

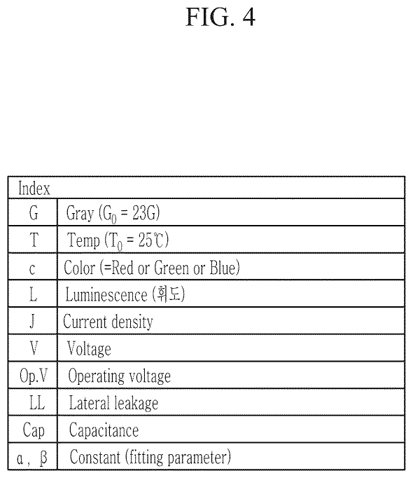

Abbreviations used in equation 1 and the like are described in more detail through FIG. 4.

FIG. 4 is a table showing the meaning of the abbreviations used in the disclosure.

First, referring to FIG. 4, gray (G), temperature (T), color (c), luminance (L), current density (J), voltage (Voltage; V), operating voltage (Op.V), factor corresponding to lateral leakage (lateral leakage; LL; hereinafter also referred to as lateral leakage factor; see equation 5 below), capacitance (Cap), and constant (constant; α, β) are each abbreviated.

Among the above abbreviations, gray (G), temperature (T), and color (c) can be used as variables, and luminance (L), current density (J), voltage (V), and driving voltage (Op.V) may be affected by gray (G), temperature (T), and color (c).

Here, it can be seen that 23 grays among 64 grays from 0 to 63 may be used as the reference gray level (G₀), and about 25° C. may be used as the reference temperature (T₀), which is based on room temperature.

The color may mean one of red, green, and blue, and the current density (J) may be a current density corresponding to the driving voltage (Op.V).

The temperature (T) used below may be about 40° C.

However, these temperature values and the like are for specific description, and are not limited thereto.

Looking at equation 1 based on FIG. 4, it is as follows.

It is stated that the expected value (TEGAL (c, T, G)) of the luminance change of equation 1 may be a function of color, temperature, and gray, and a brief expression of equation 1 may be as shown in equation 2 below.

$$TEG Δ L ( c , T , G ) = ( 1 + Δ LF ) \times 100 ( \% ) \qquad [ equation 2 ]$$

Here, ΔLF is a luminance change factor, and comparing equation 1 and equation 2, it can be confirmed that the luminance change factor ΔLF may include a total of five factors.

The expected value of the luminance change (TEGAL(c, T, G)) may be a value such that the degree of luminance change is expressed as a percentage based on about 100% (also referred to as reference luminance).

Among the five luminance change factors (ΔLF), a most important factor in determining temperature sensitivity may be the temperature sensitivity factor TSF included in equation 3 below.

$$TSF = \frac{d ( \frac{Δ L ( c , T )}{Δ J ( c , T )}}{dV ( c )} \qquad [ equation 3 ]$$

The temperature sensitivity factor TSF of equation 3 may be a value that takes into account both voltage (V), current density (J), and luminance (L), and the capacitance can be calculated without measuring through a separate test, including only the measurement value corresponding to the first measurement group.

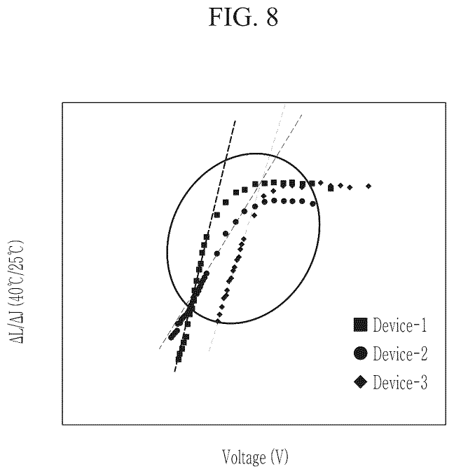

Specifically, the temperature sensitivity factor TSF may be the slope of the tangent line in the graph of ΔL/ΔJ with respect to the voltage (see FIG. 8), and the part where the temperature sensitivity is largely confirmed may be the low-scale part.

A smaller value of the temperature sensitivity factor TSF may indicate lower temperature sensitivity.

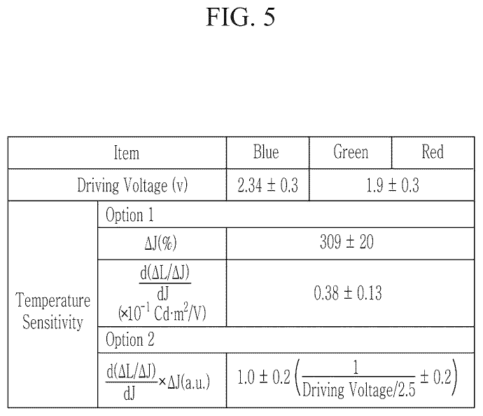

Through FIGS. 5 to 13 described below, a method for determining the temperature sensitivity of an organic light emitting element based on the temperature sensitivity factor TSF of equation 3 will be examined in more detail.

On the other hand, the second and third factors among the five luminance change factors (ΔLF) are specifically as follows.

The second of the five luminance change factors (ΔLF) may correspond to the reciprocal of the current density of a particular gray (G) to the current density of the reference gray (G₀) in each color, and additionally may include a constant a as a reciprocal number.

The third of the five luminance change factors (ΔLF) may represent the driving voltage value at the gray and/or temperature corresponding to each color.

The second and third factors may have values independent of temperature, or their values may fluctuate with temperature, but the fluctuations may not be large.

As a result, considering the temperature sensitivity of the organic light-emitting device, the temperature sensitivity may be relatively small compared to the temperature sensitivity factor TSF of equation 3, so the second and third factors may not be considered.

The fourth of the five luminance change factors (ΔLF) may be the amount of change in the current density value, which can be shown in equation 4 below.

$$Δ J ( c , T , G ) = \frac{J ( c , T , G )}{J ( c , {T}_{0} , G )} \qquad [ equation 4 ]$$

According to equation 4, the fourth factor may be the ratio of the current density corresponding to a specified temperature (T) to the current density corresponding to the reference temperature (T₀) at the same color and the same gray.

The fourth factor may have a value that fluctuates with temperature, but may be indirectly included in equation 3 in response to the change in the current density contained in equation 3.

Therefore, considering the temperature sensitivity of the organic light emitting element, the temperature sensitivity factor TSF of equation 3 may not be considered separately.

The remaining factor (the fifth factor) of the five luminance change factors (ΔLF) may be the lateral leakage factor LL, which can be shown in the following equation 5.

$$LL = 1 - ( \frac{β \times Δ Cap ( c , T ) \times \vert Δ Op . V ( c , T , G ) \vert}{Op . V ( c , G )} ) \qquad [ equation 5 ]$$

The lateral leakage factor LL of equation 5 may be a value that takes into account the capacitance (Cap) and the voltage (V), and the luminance (L) or current density (J) can be calculated without measuring through a separate test, including only the measurement value corresponding to the second measurement group.

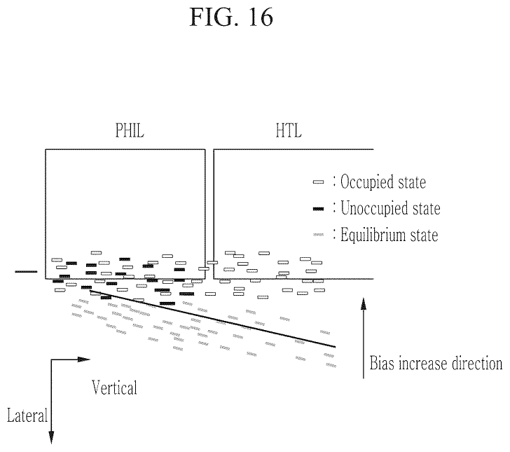

Specifically, the lateral leakage factor LL may correspond to the leakage current generated in the organic light emitting element, corresponding to the amount in which electrons or holes leak without moving between the cathode and the anode (see FIG. 16).

The larger the lateral leakage factor LL, the greater the lateral leakage, indicating that less current flows between the cathode and the anode, so the fluctuation of luminance with temperature (hereinafter referred to as temperature sensitivity due to lateral leakage) may be relatively small.

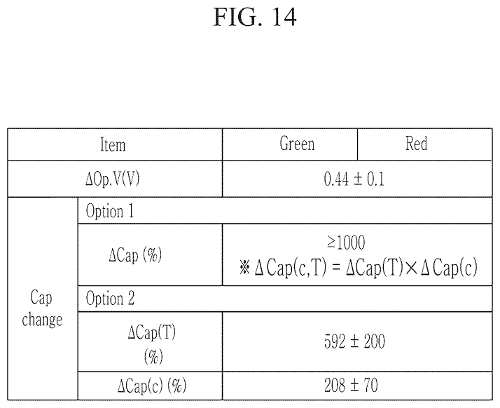

Through FIGS. 14 to 21 described below, the lateral leakage factor LL of equation 5 is specifically examined, and the temperature sensitivity of the organic light emitting element according to the lateral leakage factor LL value is examined in greater detail.

First, hereinafter, the temperature sensitivity factor TSF of equation 3 will be examined in detail through FIGS. 5 to 13.

Referring to equation 3, the temperature sensitivity factor TSF may be a factor that allows the temperature sensitivity of the organic light emitting element to be confirmed through a change in current density (J) and luminance (L) according to a change in temperature (T), and the amount of change in luminance (ΔL) relative to the amount of change in current density (ΔJ) may be a derivative value with respect to voltage (V).

The temperature sensitivity factor TSF may mean the slope of the tangent line on a graph (see FIG. 8) with the x-axis as the voltage (V) and the y-axis as ΔL/ΔJ.

Referring to equation 3, the amount of change (ΔJ) of current density and the amount of change (ΔL) of luminance may be a function of color (c) and temperature (T), respectively, and voltage (V) may be a function of color (c).

Here, the current density (J) may be defined by the driving voltage (Op. V).

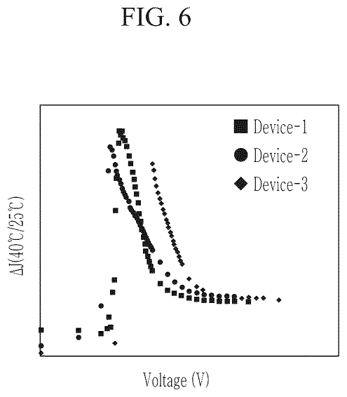

Each value (ΔJ, ΔL, V) of equation 3 may be a value that varies according to the gray, but referring to FIGS. 6 to 8, the luminance of the organic light emitting element may vary greatly in the low-scale part depending on the temperature.

The temperature sensitivity of the organic light emitting element can be confirmed through the temperature sensitivity factor TSF in the low gray.

Here, as in the low gray, a part of the gray range among grays smaller than 23 grays, which is the reference gray (G₀), may be used.

The larger the temperature sensitivity factor TSF of equation 3, the more sensitive it may be to temperature changes, so the lower the temperature sensitivity factor TSF, the more luminance and/or color of the display device may not change with temperature, so that the display quality can be improved.

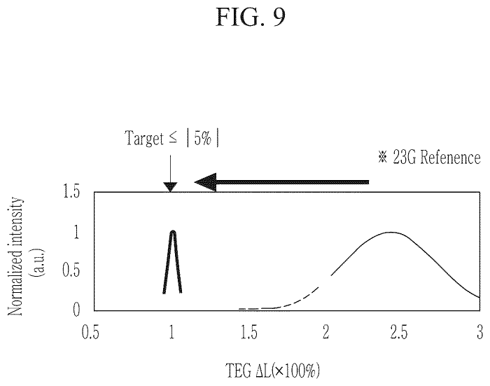

As shown in FIG. 9, the temperature sensitivity factor TSF having an expected value (TEGAL) of the luminance change within about 5% with respect to the reference luminance (about 100%) and the range of related values are tabulated in FIG. 5.

FIG. 5 is a table showing a range that can satisfy the temperature sensitivity of the organic light emitting element according to an embodiment.

In FIG. 5, the driving voltage (Op.V) values are described separately according to the color (c), and the same driving voltage may be used for the organic light emitting element displaying green and the organic light emitting element displaying red, and the organic light emitting element displaying blue may be used at a higher voltage.

Specifically, referring to FIG. 5, the blue driving voltage may have a value of 2.04V to 2.64V or less, and the green and red driving voltages may have a value of 1.6V to 2.2V or less.

The driving voltage of blue and the driving voltage of green and red may differ by a value of 0.34V to 0.54V or less.

In FIG. 5, the temperature sensitivity of the organic light emitting element is described in addition to using the temperature sensitivity factor TSF corresponding to equation 3, and additionally confirmed through the amount of change in current density (ΔJ).

The amount of change in the current density of FIG. 5 may be the fourth factor among the five luminance change factors ΔLF, and may be equal to equation 4 above.

According to Option 1 of FIG. 5, even if the temperature of the organic light emitting element is changed, the luminance may be changed within about 5% with respect to the reference luminance, and the temperature sensitivity factor TSF corresponding to equation 3 is 0.38×10⁻¹ Cd·m²/±V—that is, 0.25×10⁻¹ Cd·m²/V and 0.51×10⁻¹ Cd·m²/V or less.

On the other hand, the amount of change in the current density ΔJ may have a value of ±20% based on about 309%-that is, a value of not less than about 289% and not more than about 329% in order to change the luminance within 5% with respect to the reference luminance.

Here, the amount of change in the current density ΔJ may be a value satisfying equation 4.

On the other hand, according to Option 2 of FIG. 5, even if the temperature of the organic light emitting element is changed, the change in luminance within about 5% of the reference luminance is a temperature sensitivity factor TSF corresponding to equation 3, and a change in current density (ΔJ) may be considered together.

The multiplied value may correspond to a value within a range formed by the values described in FIG. 5.

In case that the numerical range of Option 1 or Option 2 of FIG. 5 is satisfied, it can be confirmed that the organic light emitting diode has low temperature sensitivity because the luminance of the organic light emitting element changes within about 5% of the reference luminance even in case that the temperature is changed.

Hereinafter, the meaning of the temperature sensitivity factor TSF corresponding to equation 3 will be examined in detail through FIG. 6 to FIG. 8.

FIGS. 6 to 8 are schematic views illustrating the meanings of formulas corresponding to temperature sensitivity of an organic light emitting element according to an embodiment.

FIGS. 6 to 8 are graphs showing the temperature sensitivity factor TSF of equation 3 and each item included therein.

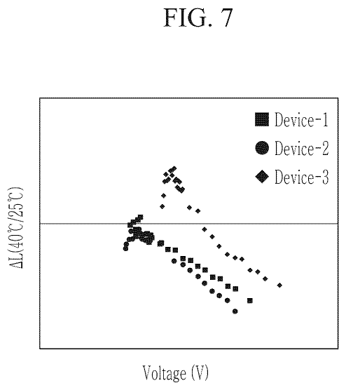

FIG. 6 shows the change in current density versus voltage (ΔJ), FIG. 7 shows the change in luminance versus voltage (ΔL), and FIG. 8 is a graph showing ΔL/ΔJ versus voltage.

In FIGS. 6 to 8, information on three elements is described, and each may be an organic light emitting element having different emission layers or may include emission layers displaying different colors.

FIG. 8 is a graph showing the value obtained by dividing the change in luminance (ΔL) in FIG. 7 by the change in current density (ΔJ) in FIG. 6 for each voltage.

Since the temperature sensitivity factor TSF of equation 3 may be a value obtained by differentiating the graph of FIG. 8, it may correspond to the slope of the tangent line in the graph of FIG. 8.

Although the slope of the tangent changes according to the voltage/gray, since the temperature-sensitive portion is the low gray portion, the slope of the tangent at the low gray portion for each element is shown as a dotted line.

The slope of the illustrated dotted line may correspond to the magnitude of the temperature sensitivity factor TSF, and the lower the slope, the lower the temperature sensitivity of the device.

In FIG. 8, it can be confirmed that Device-2 may have the lowest temperature sensitivity.

Hereinafter, the numerical range of FIG. 5 of the temperature sensitivity factor TSF of equation 3 will be examined in detail through FIGS. 9 to 13.

FIG. 9 to FIG. 12 are schematic views showing values corresponding to temperature sensitivity of an organic light emitting diode and characteristics thereof according to an embodiment, and FIG. 13 is a table of the same.

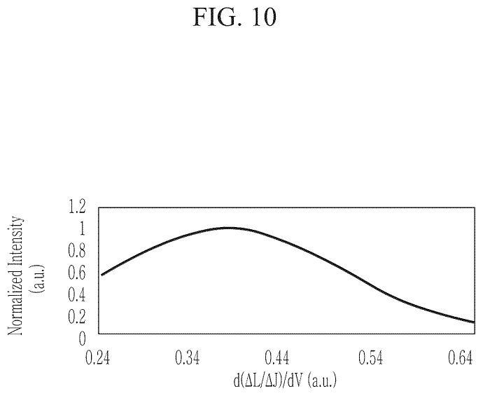

First, in FIG. 9, a target range in which the expected value (TEGAL) of the luminance change according to equation 1 may have a variation within about 5% with respect to the reference luminance (about 100%) is shown, and the temperature in case that the range is in the range A sensitivity factor TSF, a driving voltage (Op.V), and a change in current density (ΔJ) are shown in FIGS. 10 to 12, respectively.

FIGS. 9 to 12 indicate that there is no separate unit as an arbitrary unit (a.u.).

In FIGS. 9 to 12, the y-axis represents a normalized intensity without a unit, and means the intensity at which the value corresponding to the x-axis is distributed.

Referring to FIG. 9, although the expected value of the luminance change (TEGΔL) at 23 gray levels, which is the reference gray level, may have a value exceeding about 200%, it may have the drawback of being relatively sensitive to temperature and may have a value equivalent to about 100% display quality which may be improved by using an organic light emitting element that is insensitive to temperature in a display device.

In FIG. 10, in case that the expected value of the luminance change (TEGΔL) of Equation 1 is within about 5% of the reference luminance (about 100%), the temperature sensitivity factor TSF of equation 3 described on the x-axis is counted as 10, it can be seen that it may have the largest value at about 0.38.

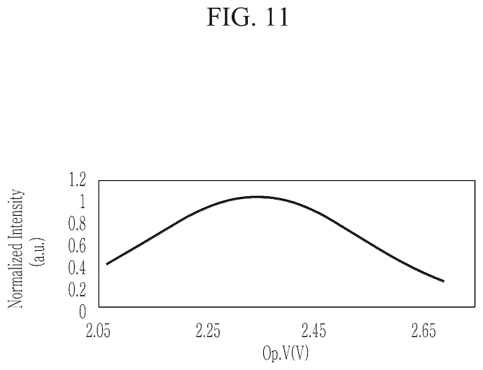

In FIG. 11, in case that the expected value of luminance change (TEGΔL) of equation 1 is within about 5% of the reference luminance (about 100%), counting the values of the driving voltages (Op.V) results in it forming the same intensity distribution, and it may have the largest value at about 2.34V.

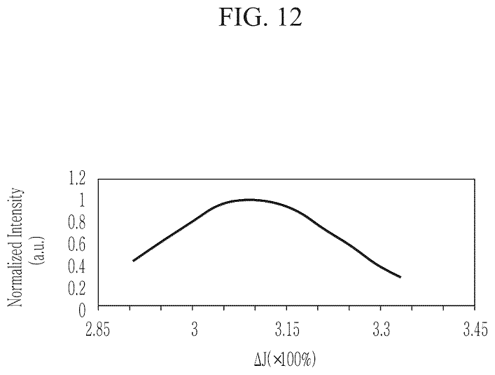

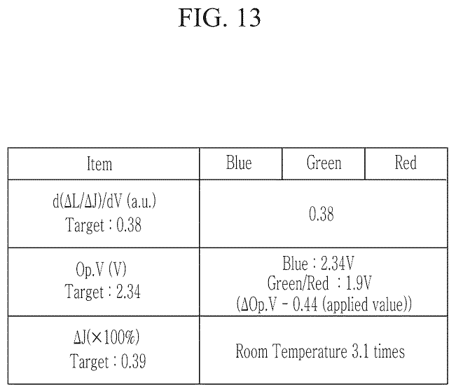

In FIG. 12, in case that the expected value of the luminance change (TEGΔL) of equation 1 is within about 5% of the reference luminance (about 100%), counting the value of the current density change (ΔJ), it may have the same intensity distribution and may have the largest value at about 309%.

In the above, the reference temperature (T₀) may be about 25° C., and the changed temperature may be about 40° C.

Therefore, in FIG. 12, the changed current density at about 40° C. based on about 25° C. is about 3.1 times greater than the current density at about 25° C.

In FIGS. 10 to 12, a numerical value having the largest distribution is set as a target value, and is summarized in a table as shown in FIG. 13. Referring to FIG. 13, the target value of the temperature sensitivity factor TSF of equation 3 may be about 0.38 for all colors (blue, green and red), and the target value of the driving voltage (Op.V) which is blue, may be about 2.34, and if about 0.44 is subtracted from green and red, which is about 1.9, and the change in current density (ΔJ) has a value of about 3.1 times that of room temperature.

In the table of FIG. 13, the unit is omitted and described, and in case changed to a value in the range based on the target value of FIG. 13, it may be the same as the numerical value shown in FIG. 5.

As described above, since the value corresponding to the temperature sensitivity factor TSF of equation 3 can be calculated only with luminance, current density, and voltage, it can be expected only with the J-V-L characteristic test, and the capacitance can be calculated through additional tests. It is not necessary, and there is a benefit in that the change in luminance/color sense according to the temperature of the organic light emitting element can be grasped with only one simple test.

Hereinafter, the lateral leakage factor LL of equation 5 will be examined in detail through FIGS. 14 to 21.

Referring to equation 5, the lateral leakage factor LL may be calculated based on the driving voltage (Op.V) and capacitance (Cap) values, and the factors constituting the lateral leakage factor LL may exclude the constant (0), and it can contain three arguments.

Among the three factors constituting the lateral leakage factor LL, the first factor may be the change in capacitance (Δcap (c, T)), and the second and third factors may be factors for the driving voltage, respectively, the change in driving voltage (ΔOp.V (c, T, G)) and driving voltage (Op.V (c, G)).

First, the capacitance variation (ΔCap (c, T)), which may be the first factor, is described in detail as equation 6 below.

$$Δ Cap ( c , T ) = \vert \frac{{Cap}_{m ax}^{′} ( c , T ) - {Cap}_{m ax} ( c , {T}_{0} )}{{Cap}_{m ax}^{′} ( c = Blue , T ) - {Cap}_{m ax} ( c = Blue , {T}_{0} )} \vert \times \frac{{Cap}_{m ax}^{′} ( c , T )}{{Cap}_{m ax} ( c , T )} \qquad [ equation 6 ]$$

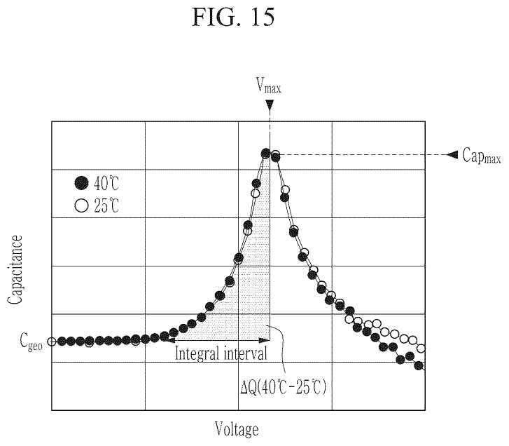

The Capₘₐₓ described in equation 6 may represent the maximum value in the graph of capacitance as shown in FIG. 15, and Cap′ₘₐₓ is specifically as shown in equation 7 below.

$${Cap}_{m ax}^{′} ( c , T ) = {Cap}_{ma x} ( c , T ) / {ΔV}_{ma x} ( c , T ) \qquad [ equation 7 ]$$

The amount of change in the maximum voltage (ΔVₘₐₓ) described in equation 7 is shown in equation 8 below.

$$Δ {V}_{max} ( c , T ) = {V}_{max} ( c , T ) / {V}_{max} ( c , {T}_{0} ) \qquad [ equation 8 ]$$

Here, Vmax may be a voltage value in case that the capacitance (Capₘₐₓ) has the maximum value in the graph as shown in FIG. 15, and the change amount (ΔVₘₐₓ) of the maximum voltage may represent the change amount of the Vmax value according to temperature.

As described above, the first factor of the lateral leakage factor LL can be calculated based only on the capacitance (Cap) and the voltage (V).

The second factor of the lateral leakage factor LL, the amount of change in the driving voltage (ΔOp.V (c, T, G)) is specifically expressed in equation 9.

$$Δ Op . V ( T , G ) = maximum value among ( Red - Blue ) \& ( Green - Blue ) \qquad [ equation 9 ]$$

According to equation 9, the amount of change in the driving voltage (ΔOp.V (c, T, G)) means the greater of the difference between the driving voltage between red and blue and the difference between green and blue, and the absolute value of the value of the value of equation 9 may be used in equation 5 to obtain the lateral leakage factor LL.

The third factor of the lateral leakage factor LL, the driving voltage (Op.V (c, G)) may represent the driving voltage according to color and gray.

The lateral leakage factor LL as described above may correspond to the magnitude of the current leakage in the organic light emitting element, and referring to equation 5, the first factor, the second factor, and the third factor of the lateral leakage factor LL.

If the value of the lateral leakage factor LL is large, the fluctuation of the current flowing between the two electrodes (cathode, anode) of the organic light emitting element may be relatively small and the fluctuation of the luminance of the organic light emitting element may also be reduced, so the change in luminance according to temperature (hereinafter, also referred to as temperature sensitivity due to lateral leakage) may also be relatively small.

In case that the value of the lateral leakage factor LL has a variation of about 10% or less based on about 1, it may correspond to a large lateral leakage current and small temperature sensitivity according to the lateral leakage.

In case that the value of the lateral leakage factor LL satisfies the variation within about 10% based on about 1, the first factor of the lateral leakage factor LL (change amount of capacitance (ΔCap (c, T)) in equation 6) and the ranges of values associated therewith are tabulated in FIG. 14.

FIG. 14 is a table showing a range of capacitance values capable of satisfying lateral leakage of an organic light emitting element according to an embodiment.

All values described in FIG. 14 are the difference between values in green and/or red based on blue, and the temperatures are calculated based on about 40° C. and about 25° C.

Therefore, color (c) may be either green or red.

The amount of change in driving voltage (ΔOp.V) shown in FIG. 14 is the difference between the driving voltage of the organic light emitting element displaying blue and the driving voltage of the organic light emitting element displaying green and/or red is the value.

In an embodiment, the green and red driving voltages use the same driving voltage, and the driving voltage variation (ΔOp.V) may have a value of about 0.34V or more and about 0.54V or less.

The numerical range of the capacitance change amount (ΔCap) in equation 6, which is the first factor of the lateral leakage factor LL, has a value of about 1000% or more, which is green for an organic light emitting element displaying blue and/or the value of capacitance variation (ΔCap) of the organic light emitting element displaying red may be about 10 times or more.

Referring to FIG. 14, the capacitance variation ΔCap in equation 6 may be calculated using equation 10 below.

$$Δ Cap ( c , T ) = Δ Cap ( T ) \times Δ Cap ( c ) \qquad [ equation 10 ]$$

Here, ΔCap(T) may be the amount of change in capacitance for each temperature, and ΔCap(c) may be the amount of change in capacitance for each color, which may be the Capₘₐₓ−C_{geo} value of FIG. 15.

Here, C_{geo} means a capacitance value that exists even in case that there is no voltage, and may be a value of a y-intercept in the capacitance versus voltage graph of FIG. 15.

The temperature may be calculated based on various temperatures, for example, based on about 42 degrees and about 25 degrees.

Both equation 10 and equation 6 may equally represent the amount of change in capacitance (ΔCap), which may be the first factor of the lateral leakage factor LL, and may be more simplified representations of the complex equation of equation 6.

The first and second factors described in the amount of change in capacitance (Δcap) in equation 6 may correspond to the second factor and the first factor described in the amount of change in capacitance (Δcap) in equation 10, respectively.

Referring to Option 2 of FIG. 14, the numerical ranges for the first and second factors of the capacitance variation (ΔCap) in equation 10 are described.

The capacitance change amount (ΔCap(T)) according to temperature, which may be the first factor of the capacitance change amount (ΔCap), may be the value of the capacitance change amount (ΔCap) of green and/or red with respect to blue. In case that it has a value of about 10 times or more, it has a range of about 200% up and down based on about 592%, and can have a value of about 392% or more and about 792%.

The second factor of the capacitance change amount (ΔCap), the capacitance change amount (ΔCap(c)) according to the color may be the capacitance change amount (ΔCap) of green and/or red with respect to blue. In case that it has a value of about 10 times or more, it has a range of about 70% up and down based on about 208%, and may have a value of about 138% or more and about 278%.

As shown in FIG. 14, in case that the numerical range of Option 1 or Option 2 is satisfied, the value of the lateral leakage factor LL satisfies the variation within about 10% based on about 1, so the lateral leakage value may be large and the temperature sensitivity may be high, and the falling organic light emitting element can be confirmed.

Hereinafter, the meaning of the lateral leakage factor LL corresponding to equation 5 will be examined in detail through FIGS. 15 and 16.

FIGS. 15 and 16 are schematic views illustrating the meanings of equations corresponding to lateral leakage of an organic light emitting element according to an embodiment.

First, in FIG. 15, a graph of capacitance versus voltage according to temperature is shown, and in FIG. 16, in case that electrons or holes move while the occupied state and unoccupied state are changed in the organic light emitting element, an equilibrium state may occur additionally according to the change in temperature, a state in which leakage occurs in a lateral direction through the state is also shown.

As shown in FIG. 16, the value leaked to the side depending on the temperature can be determined based on the change in capacitance according to the temperature, and the change in the amount of charge (Q) in the integration section up to the maximum value (Capₘₐₓ) of the capacitance shown in FIG. 15 (ΔQ) can be expected.

In FIG. 16, the region marked by the rain may correspond to the amount of change in the amount of charge (ΔQ), and the smaller the amount of change in the amount of charge (ΔQ) in the organic light emitting element, the smaller the leakage current.

On the other hand, the amount of change in capacitance (ΔCap) of equation 6 and/or equation 10 also may correspond to the rain region of FIG. 16 because the amount of change in the amount of charge (ΔQ) in the organic light emitting element may be proportional to the amount of change in the capacitance (ΔCap).

Therefore, the lateral leakage factor LL of equation 5 may be based on the amount of change in capacitance (ΔCap) corresponding to the amount of change in charge (ΔQ), which may move charges or holes in the lateral direction within the organic light emitting element, and so it may be possible to predict the extent to which the ratio of carrier transport changes with temperature.

As a result, the degree of lateral leakage of the organic light emitting element can be confirmed based on equation 5.

The lateral leakage factor LL in equation 5 may be a value considering the capacitance (Cap) and voltage (V), and may include only the measured values corresponding to the second measurement group to luminance (L) or current density (J) through a separate test that can be calculated without measurement.

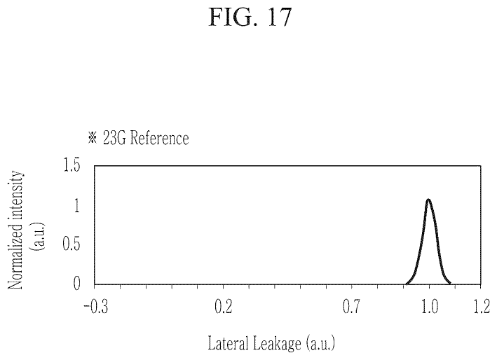

Hereinafter, the numerical range of FIG. 14 of the capacitance variation (ΔCap) in equation 6 and/or equation 10 will be examined in detail through FIGS. 17 to 21.

FIG. 17 to FIG. 20 are schematic views showing numerical values corresponding to lateral leakage of an organic light emitting element and characteristics thereof according to an embodiment, and FIG. 21 is a table of the same.

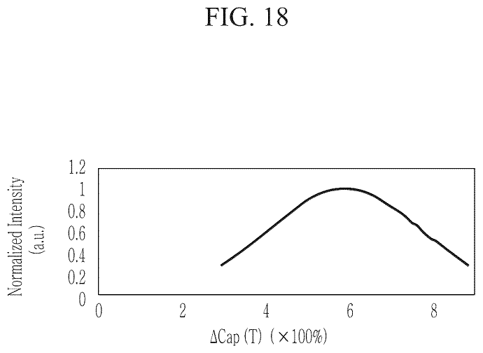

First, in FIG. 17, the value of the lateral leakage factor LL according to equation 5 is shown as a target range with a value having a variation of about 10% or less based on about 1, and capacitance according to temperature in the corresponding range the amount of change (ΔCap(T)), the amount of change in capacitance according to color (ΔCap (red or green/blue)), and the driving voltage (Op.V) are shown in FIGS. 18 to 20, respectively.

FIGS. 17 to 20 indicate that there may be no separate unit as an arbitrary unit (a.u.).

In FIGS. 17 to 20, the y-axis represents a normalized intensity without a unit, and means the intensity at which the value corresponding to the x-axis is distributed.

Referring to FIG. 17, values corresponding to FIGS. 17 to 20 are values calculated at gray level 23, which is a reference gray level.

As shown in FIG. 17, in case that the value of the lateral leakage factor LL according to equation 5 is within about 10% of 1—that is, a value of about 0.9 or more and about 1.1 or less-relatively large lateral leakage may cause temperature fluctuations, since the change in luminance of the organic light emitting element may not be large even according to the temperature, and a display device that may be insensitive to temperature can be configured using the corresponding organic light emitting element, and the display quality of the display device can be constant regardless of temperature change.

In FIG. 18, in case that the value of the lateral leakage factor LL is about 0.9 or more and about 1.1 or less, in case that the capacitance change amount (ΔCap(T)) according to the temperature indicated on the x-axis is counted, the intensity distribution shown in FIG. 18 may be obtained, and it may have the largest value at about 592%.

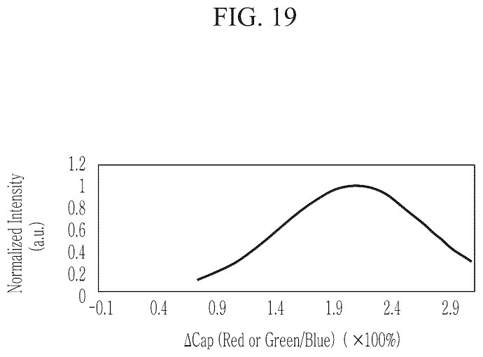

On the other hand, in FIG. 19, in case that the value of the lateral leakage factor LL is about 0.9 or more to about 1.1 or less, the amount of capacitance change (ΔCap (red or green/blue)) according to color may be counted, respectively, and the intensity distribution may be the same as in FIG. 19, and it may have the largest value at about 208%.

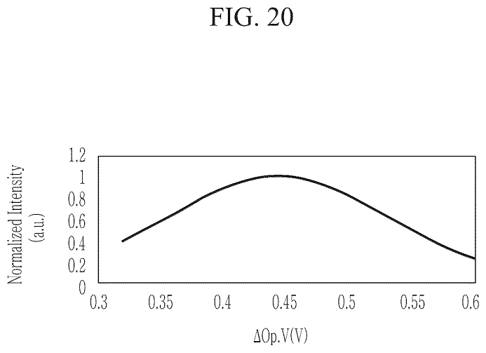

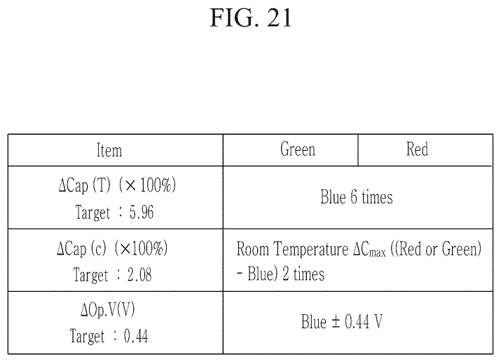

In FIG. 20, in case that the value of the lateral leakage factor LL is about 0.9 or more and about 1.1 or less, in case that the amount of change (ΔOp.V) of the driving voltage is counted, the intensity distribution shown in FIG. 20 may be obtained, and may have the largest value at about 0.44V.

In the above, the reference temperature (T₀) may be about 25° C., the changed temperature may be about 40° C., and the value in green or red may be calculated based on blue.

FIGS. 18 to 20 are summarized in a table with the numerical value having the largest distribution as a target value, as shown in FIG. 21.

Referring to FIG. 21, the target value of the capacitance change amount (ΔCap(T)) according to temperature is about 592%, and the capacitance change amount (ΔCap(T)) in green or red with respect to blue may have about a six-fold value before and after.

The target value of the capacitance change amount (ΔCap (red or green/blue)) according to the color is about 208%, and the capacitance change amount (ΔCap (red or green/blue)) may have around a two-fold value.

The target value of the change in the driving voltage (ΔOp.V) is about 0.44V, and the difference value between the blue driving voltage and the green or red driving voltage may be about 0.44V.

Based on the target value described in FIG. 21, if it is changed to a range value, it may be the same as the value described in FIG. 14.

As described above, since the value corresponding to the lateral leakage factor LL of equation 5 can be calculated only with capacitance and voltage, it can be expected only with a C-V characteristic test, and luminance or current density can be calculated through an additional J-V-L test, such testing is not necessary, and there is an advantage in that lateral leakage of an organic light emitting element can be expected with only one simple test.

In the above, in order to calculate the expected value (TEGΔL(c, T, G)) of the luminance change corresponding to equation 1, the temperature sensitivity factor TSF of equation 3 and related contents and lateral leakage factor LL of equation 5 and its related contents are examined in detail.

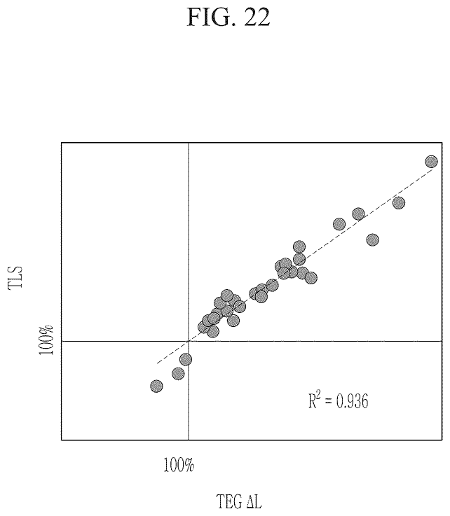

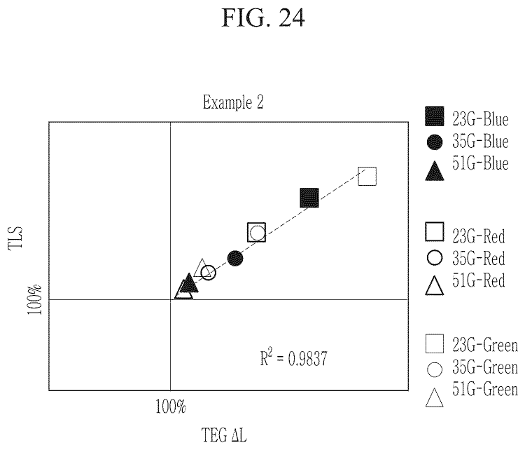

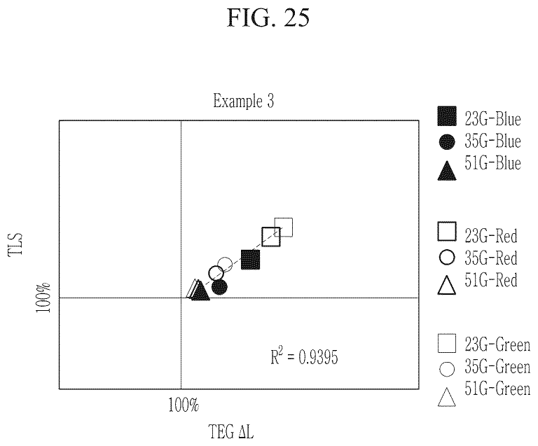

Hereinafter, through FIGS. 22 to 25, the expected value (TEGΔL(c, T, G)) of the luminance change corresponding to equation 1 may have a relationship with the actual measured luminance change value TLS.

For example, in FIGS. 22 to 25, the expected value (TEGΔL (c, T, G)) of the luminance change of equation 1 may be less different from the actual luminance change, so that the prediction using the expected value (TEGΔL (c, T, G)) of the luminance change of equation 1 may be reliable.

FIGS. 22 to 25 are schematic graphs showing the relationship between an expected value and an actual value of a change in luminance according to temperature.

In FIGS. 22 to 25, the expected value (TEGΔL) of the luminance change according to equation 1 including the temperature sensitivity factor TSF and the actual measurement value TLS of the luminance change measured based on the temperature change are compared to show whether it is a reliable factor for temperature sensitivity.

Specifically, the expected value (TEGΔL) of the luminance change described in the x-axis may be based on the luminance (L), current density (J), voltage (V), and capacitance (Cap) values obtained through the test.

The actual value TLS of the luminance change described on the y-axis may be the actual value of the change in luminance emitted by the organic light-emitting element under the same conditions.

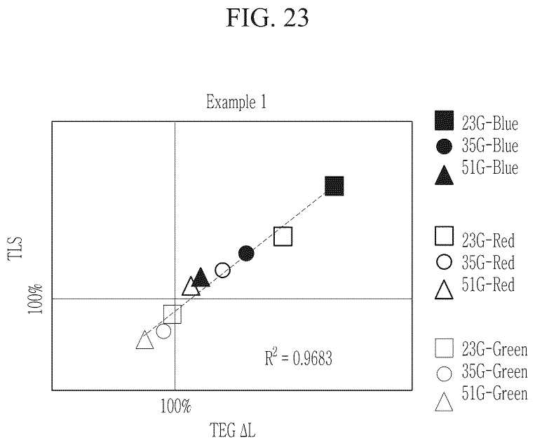

FIGS. 23 to 25 are graphs showing the measured value TLS of the luminance change amount with respect to the expected value (TEGΔL) of the luminance change amount for embodiment 1, embodiment 2, and embodiment 3, respectively, and the results of FIGS. 23 to 25 are combined and shown in FIG. 22.

In FIGS. 23 to 25, for each embodiment, the organic light emitting element of red, green, and blue may be calculated and measured using an example of displaying 23 gradations (G), 35 gradations (G), and 51 gradations (G), respectively.

The dotted lines shown in FIGS. 22 to 25 represent a trend line based on the results of each experiment, and the R² value shown in each drawing may be a coefficient of determination, indicating the degree to which each point deviates from the trend line.

The coefficient of decision (R²) may be larger, indicating that it is positioned above the trend line.

From FIGS. 23 to 25, it can be seen that embodiment 3 may have the smallest coefficient of determination (R²), and may be relatively far away from the trend line.

However, the coefficient of decision (R²) may be high overall and may not be positioned far from the trend line, and based on the coefficient of determination (R²), about 90% may be obtained based on the expected value (TEGΔL) of the luminance change calculated based on equation 1. It can be seen that there may be a high predictive power.

Therefore, it can be seen that the luminance change based on the temperature sensitivity of the organic light emitting element can be accurately expected only through equation 1 alone and only with the expected value of the luminance change amount (TEGΔL).

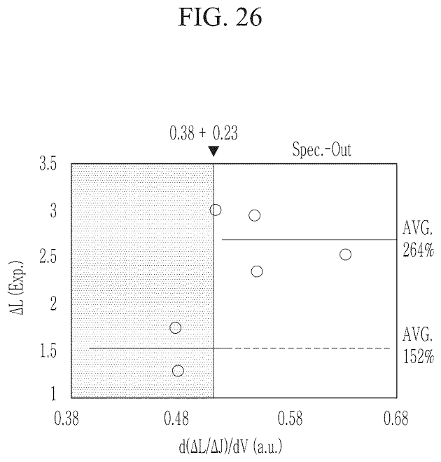

Hereinafter, the results of experiments to determine whether temperature sensitivity is improved in case that the numerical ranges of FIG. 5 and FIG. 14 are met through FIGS. 26 to 28 will be examined.

FIGS. 26 to 28 are schematic graphs illustrating temperature sensitivity, driving voltage, and capacitance values corresponding to lateral leakage according to an embodiment.

First, FIG. 26 is a graph of the luminance variation (ΔL) with respect to the temperature sensitivity factor TSF value of equation 3.

Here, the y-axis represents the exponential function value of the luminance variation (ΔL), so a difference of about 1 can represent a difference of about 100%.

Referring to FIG. 26, in case that the temperature sensitivity factor (TSF) value is smaller than about 0.38+0.13, which may be the largest value among the temperature sensitivity factor (TSF) values described in FIG. 5, the average may be reduced from about 264% to about 152%, and in case within the range of the temperature sensitivity factor (TSF) described, it can be seen that the luminance change may be reduced by an average of about 112%.

Therefore, in case that the numerical range of the temperature sensitivity factor (TSF) of FIG. 5 is satisfied, the change in luminance according to temperature may be small, indicating that the temperature sensitivity may be small.

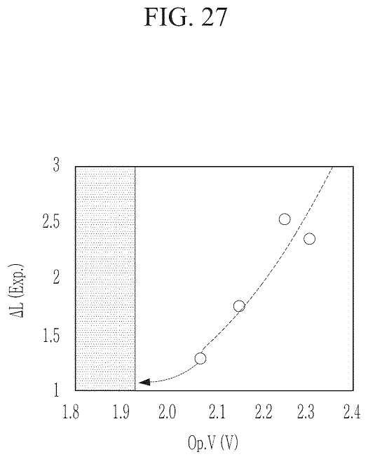

In FIG. 27, a graph of the luminance change (ΔL) versus the driving voltage (Op.V) is shown, and the y-axis represents an exponential function value of the luminance change (ΔL).

Referring to FIG. 27, it can be seen that the luminance variation (ΔL) may decrease as it approaches about 1.9, which may be the median value of the green and red driving voltages (Op.V) described in FIG. 5.

Therefore, it can be confirmed that the temperature sensitivity may be small because the luminance change according to the temperature may be small.

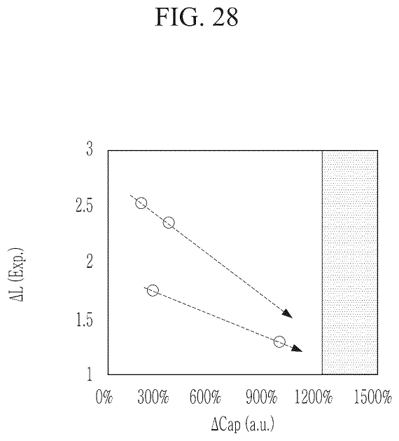

In FIG. 28, a graph of the luminance change (ΔL) against the capacitance change (Δcap) is shown, and the y-axis represents the exponential function value of the luminance change (ΔL).

Here, the change in capacitance (ΔCap) may be the change in capacitance (ΔCap) described in equation 6 or equation 10 required to obtain the lateral leakage factor LL in equation 5.

Referring to FIG. 28, as mentioned in FIG. 14, it can be seen that the luminance change (ΔL) decreases as the capacitance change (Δcap) approaches about 1000%.

Therefore, it can be confirmed that the luminance change with temperature may be small, and the temperature sensitivity may be small.

On the other hand, according to an embodiment, the emission layer and/or the functional layer of the organic light emitting element may be formed into a material having high mobility to adjust the current density to reduce the brightness change according to the temperature of the organic light emitting element.

Here, the organic material of the emission layer and/or the functional layer included in the organic light emitting material uses an organic material having a mobility of 1e⁻⁶ cm²/V·s or more, respectively, to reduce the disadvantage of increasing the amount of lateral leakage depending on the temperature in case that the mobility is low.

On the other hand, each layer included in the organic light emitting element may be formed to have an energy gap of about 0.2 eV or less, and the above described energy difference can be satisfied both between the electrode and the functional layer, and between the functional layer and the emission layer.

Specifically, as shown in FIG. 3, in case that the organic light emitting element has an anode, a first functional layer FL1, an emission layer (EML), a second functional layer FL2, and a cathode, an energy gap between the two adjacent layers of the anode, the first functional layer FL1, the emission layer (EML), the second functional layer FL2, and the cathode may be about 0.2 eV or less, respectively.

A material with a work function between heterogeneous materials in an organic light emitting element or an energy gap between the Highest Occupied Molecular Orbital (HOMO) and the Lowest Unoccupied Molecular Orbital (LUMO) of about 0.2 eV or less can be used.

An organic light emitting element having an energy gap of about 0.2 eV or less between each layer may have a mobility of 1e⁻⁶ cm²/V·s or more.

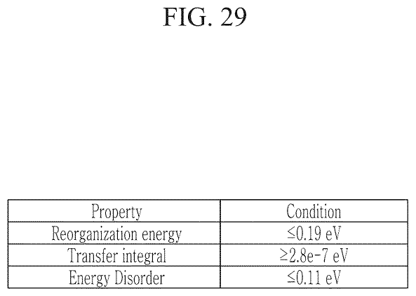

Hereinafter, the physical properties required for the material used in the organic light emitting element are examined through FIG. 29 in order to have the above high mobility and/or a low energy gap below a certain level.

FIG. 29 is a table describing conditions according to the physical properties of an organic light emitting element according to an embodiment.

The physical properties of FIG. 29, based on Marcus theory which are factors included in the Marcus equation, such as reorganization energy, transfer integral, and energy disorder, are described.

In FIG. 29, reorganization energy may be energy required for a material used in an organic light emitting element to move electrons or holes, and according to FIG. 29, a material having a value of about 0.19 eV or less as reorganized energy can be configured for an organic light emitting element.

Transfer integral may be an energy value in which electrons bound to one atom in organic matter can move to the orbit of another atom, and according to FIG. 29, about 2.8 e⁻⁷ eV or more.

Energy disorder may be a value indicating the degree to which the energy distribution is different according to location in the material, and according to FIG. 29, an organic light emitting device can be constructed using a material having a value of about 0.11 eV or less as an energy disorder value.

An organic light emitting element can be configured to have high mobility by using a material that satisfies the reorganization energy, transfer integral, and energy disorder values described in FIG. 29.

Depending on the embodiment, an organic light emitting element may be constructed from a material that satisfies only some of these conditions.

In manufacturing an organic light emitting element, the following items can be applied to form an organic light emitting element with low sensitivity to temperature.

In the above, some of the numerical ranges are described without including an upper or lower limit, because the numerical range is sufficiently effective even if there is no upper or lower limit, and even if there is no upper or lower limit, considering the size of the device, etc., there may be a substantial upper limit because it cannot be indefinite, or there may be a substantial lower limit because it must be greater than zero.

Therefore, even if there is no upper or lower limit, it is not unclear.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display device, comprising:
a red pixel, a green pixel, and a blue pixel that each include a plurality of transistors and an organic light emitting element, wherein:
the organic light emitting element has a value of a temperature sensitivity factor (TSF) in a range of about 0.25×10⁻¹ Cd·m²/V to about 0.51×10⁻¹ cd·m²/V as shown in a following equation:
$$T S F = \frac{d ( \frac{Δ L ( c , T )}{Δ J ( c , T )} )}{dV ( c )} ,$$
where ΔJ is an amount of change in current density,
where ΔL is an amount of change in luminance,
where V is a voltage,
where a variable c is a color, and
where T is a temperature.

2. The display device of claim 1, wherein the temperature sensitivity factor (TSF) is a slope of a tangential line on a graph having an x-axis as a voltage and a y-axis as ΔL/ΔJ.

3. The display device of claim 2, wherein a driving voltage for the organic light emitting element of the blue pixel has a voltage higher than a driving voltage for the organic light emitting element of the red pixel and a driving voltage for the organic light emitting element of the green pixel.

4. The display device of claim 3, wherein
the driving voltage for the organic light emitting element of the blue pixel has a voltage in a range of about 2.04V to about 2.64V, and
the driving voltage for the organic light emitting element of the red pixel and the driving voltage for the light emitting element of the green pixel may each be in a range of about 1.6V to about 2.2V.

5. The display device of claim 1, wherein the organic light emitting element of at least one of the red pixel, the green pixel, and the blue pixel changes a luminance to within about 5% of a reference luminance even in case that the temperature is changed.

6. The display device of claim 5, wherein
an expected value (TEGΔL) of a luminance change of the organic light emitting element of at least one of the red pixel, the green pixel, and the blue pixel satisfies a following equation:
$$TEG Δ L ( c , T , G ) = ( 1 + \frac{d ( \frac{Δ L ( c , T )}{Δ J ( c , T )} )}{dV ( c )} \times \frac{1}{a} \frac{J ( c , {G}_{0} )}{J ( c , G )} \times Op . V ( c , G ) \times ( Δ J ( c , T , G ) \times LL ) ) \times 100$$
where Op.V is a driving voltage, LL is a lateral leakage factor, and a is a constant.

7. The display device of claim 6, wherein
the amount of change of a current density value (ΔJ(c, T, G)) included in an expected value of a luminance change satisfies a following equation, and has a value in a range of about 289% to about 329%:
$$Δ J ( c , T , G ) = \frac{J ( c , T , G )}{J ( c , {T}_{0} , G )} .$$

8. The display device of claim 6, wherein
the lateral leakage factor LL satisfies the following equation:
$$L L = 1 - ( \frac{β \times Δ Cap ( c , T ) \times \vert Δ Op . V ( c , T , G ) \vert}{Op . V ( c , G )} ) ,$$
where Cap is capacitance and β is a constant.

9. The display device of claim 8, wherein:
an amount of change in capacitance (ΔCap(c, T)) among lateral leakage factors satisfies a following equation:
$$Δ Cap ( c , T ) = \vert \frac{{Cap}_{max}^{′} ( c , T ) - {Cap}_{max} ( c , {T}_{0} )}{{Cap}_{max}^{′} ( c = Blue , T ) - {Cap}_{max} ( c = Blue , {T}_{0} )} \vert \times \frac{{Cap}_{max}^{′} ( c , T )}{{Cap}_{max} ( c , {T}_{0} )}$$
where Cap′ₘₐₓ satisfies the following equation,
$${Cap}_{max}^{′} ( c , T ) = {Cap}_{max} ( c , T ) / Δ {V}_{max} ( c , T ) ,$$
where an amount of change of a maximum voltage ΔVmax satisfies a following equation:
$$Δ {V}_{max} ( c , T ) = {V}_{max} ( c , T ) / {V}_{max} ( c , {T}_{0} ) .$$

10. The display device of claim 9, wherein
the amount of change in capacitance has a value of about 1000% or more, and the amount of change in capacitance of the red pixel or the organic light emitting element of the green pixel has a value of about 10 times or more with respect to the organic light emitting element of the blue pixel.

11. The display device of claim 1, wherein the organic light emitting element of at least one of the red pixel, the green pixel, and the blue pixel has a mobility of about 1e⁻⁶ cm²/V·s or more.

12. The display device of claim 1, wherein
the organic light emitting element of at least one of the red pixel, the green pixel, and the blue pixel includes an anode, a first functional layer, an emission layer, a second functional layer, and a cathode, and
the energy gap between two adjacent layers among the anode, the first functional layer, the emission layer, the second functional layer, and the cathode is about 0.2 eV or less.

13. A display device, comprising:
a red pixel, a green pixel, and a blue pixel that each include a plurality of transistors and an organic light emitting element, wherein
the organic light emitting element has a value of about 1000% or more of an amount of change in capacitance (ΔCap(c, T)) as shown in a following equation:
$$Δ Cap ( c , T ) = \vert \frac{{Cap}_{max}^{′} ( c , T ) - {Cap}_{max} ( c , {T}_{0} )}{{Cap}_{max}^{′} ( c = Blue , T ) - {Cap}_{max} ( c = Blue , {T}_{0} )} \vert \times \frac{{Cap}_{max}^{′} ( c , T )}{{Cap}_{max} ( c , {T}_{0} )}$$
where a variable c is a color,
where T is a temperature,
where T₀ is about 25° C.,
where Cap is a capacitance,
where Cap′ₘₐₓ satisfies the following equation:
$${Cap}_{max}^{′} ( c , T ) = {Cap}_{max} ( c , T ) / Δ {V}_{max} ( c , T ) ,$$
where a maximum voltage change (ΔVmax) satisfies the following equation:
$$Δ {V}_{max} ( c , T ) = {V}_{max} ( c , T ) / {V}_{max} ( c , {T}_{0} ) .$$

14. The display device of claim 13, wherein an amount of change in capacitance of the organic light emitting element of the red pixel or the organic light emitting element of the green pixel with respect to the organic light emitting element of the blue pixel has a value of about 10 times or more.

15. The display device of claim 14, wherein a lateral leakage factor LL satisfies a following equation:
$$Δ Cap ( c , T ) = Δ Cap ( T ) \times Δ Cap ( c ) ,$$
where ΔCap(T) is an amount of change in capacitance for each temperature, and
ΔCap(c) is an amount of change in capacitance for each color.

16. The display device of claim 15, wherein a capacitance change according to a temperature has a value in a range of about 392% to about 792%.

17. The display device of claim 15, wherein a capacitance change according to color has a value in a range of about 138% to about 278%.

18. The display device of claim 14, wherein a difference between the driving voltage of the organic light emitting element of the blue pixel and the driving voltage of the organic light emitting element of the red pixel or the organic light emitting element of the green pixel has a value in a range of about 0.34V to about 0.54V.

19. The display device of claim 13, wherein an organic light emitting element of at least one of the red pixel, the green pixel and the blue pixel has a mobility of about 1e⁻⁶ cm²/V·s or more.

20. The display device of claim 13, wherein
the organic light emitting element includes an anode, a first functional layer, an emission layer, a second functional layer, and a cathode, and
an energy gap between two adjacent layers among the anode, the first functional layer, the emission layer, the second functional layer, and the cathode is about 0.2 eV or less.
